(19) United States
(12) Patent Application Publication
(10) Pub. No.: US 2025/0393359 A1
(43) Pub. Date: Dec. 25, 2025

(54) DISPLAY DEVICE AND AN ELECTRONIC DEVICE INCLUDING THE SAME

(71) Applicant: Samsung Display Co., LTD., Yongin-si (KR)

(72) Inventors: SEONG SIK AHN, Yongin-si (KR); KWANG-BOK KIM, Yongin-si (KR); DEOK-YOUNG CHOI, Yongin-si (KR); JONGHAK HWANG, Yongin-si (KR)

(21) Appl. No.: 18/983,560

(22) Filed: Dec. 17, 2024

(30) Foreign Application Priority Data
Jun. 24, 2024 (KR) 10-2024-0081699

(51) Int. Cl. H10H 29/49

(52) U.S. Cl. CPC H10H 29/49

(57) ABSTRACT

A display device includes: a 1-1 overlapping connection line overlapping a crack bypass propagation area in a plan view; a second overlapping connection line disposed on the 1-1 overlapping connection line and overlapping the crack bypass propagation area and the 1-1 overlapping connection line in the plan view; and a pixel electrode disposed on the second overlapping connection line. A part of the pixel electrode overlapping the crack bypass propagation area overlaps the 1-1 overlapping connection line and the second overlapping connection line in the plan view.

This application claims priority to Korean Patent Application No. 10-2024-0081699, filed on Jun. 24, 2024, and all the benefits accruing therefrom under 35 U.S.C. § 119, the content of which in its entirety is herein incorporated by reference.

### BACKGROUND

### Field

Implementations of the inventive concept relate generally to a display device and an electronic device including the display device.

### Discussion of the Background

A display device includes a substrate, a metal line layer, and a light emitting diode layer. The metal line layer generates a driving current, and the light emitting diode layer emits light corresponding to the driving current. The substrate, the metal line layer, and the light emitting diode layer are sequentially stacked, and the display device has a stacked structure. The metal line layer has a structure in which a plurality of metal lines are stacked, and inorganic insulating layers are arranged between the metal lines.

When an impact is applied to the upper portion of the display device, a crack occurs in the upper portion of the display device. Since the inorganic insulating layers are generally formed of a material vulnerable to impact, the crack propagates vertically. The vertically propagated crack destroys the substrate, which worsens the impact resistance of the display device.

### SUMMARY

Embodiments provide a display device.

Embodiments provide an electronic device including the display device.

A display device according to an embodiment includes: a 1-1 overlapping connection line disposed on a substrate and overlapping a crack bypass propagation area in a plan view; a second overlapping connection line disposed on the 1-1 overlapping connection line and overlapping the crack bypass propagation area and the 1-1 overlapping connection line in the plan view; and a pixel electrode disposed on the second overlapping connection line. A part of the pixel electrode overlapping the crack bypass propagation area overlaps the 1-1 overlapping connection line and the second overlapping connection line.

In an embodiment, the part of the pixel electrode may overlap an edge of the 1-1 overlapping connection line in the plan view.

In an embodiment, the part of the pixel electrode may overlap an edge of the second overlapping connection line in the plan view.

In an embodiment, the edge of the 1-1 overlapping connection line may overlap the second overlapping connection line in the plan view.

In an embodiment, each of the 1-1 overlapping connection line, the second overlapping connection line, and the pixel electrode may partially overlap the crack bypass propagation area in the plan view.

In an embodiment, the display device may further include at least one inorganic insulating layer disposed between the substrate and the 1-1 overlapping connection line. A fracture strength of the pixel electrode may be greater than a fracture strength of the at least one inorganic insulating layer.

In an embodiment, a fracture strength of the 1-1 overlapping connection line may be greater than the fracture strength of the at least one inorganic insulating layer. A fracture strength of the second overlapping connection line may be greater than the fracture strength of the at least one inorganic insulating layer.

In an embodiment, the display device may further include an overlapping lower line disposed between the substrate and the 1-1 overlapping connection line and overlapping the crack bypass propagation area, the 1-1 overlapping connection line, the second overlapping connection line, and the pixel electrode in the plan view.

In an embodiment, an edge of the 1-1 overlapping connection line may overlap the overlapping lower line in the plan view.

In an embodiment, an edge of the second overlapping connection line may overlap the overlapping lower line in the plan view.

A display device according to another embodiment includes: a pixel electrode disposed on a substrate and including a first edge, a second edge connected to the first edge, a third edge connected to the second edge, and a fourth edge connected to the third edge, a 1-1 overlapping connection line disposed between the substrate and the pixel electrode and including a first overlapping portion and a second overlapping portion, where the first and second overlapping portions overlap the pixel electrode in a plan view, a 1-2 overlapping connection line adjacent to the 1-1 overlapping connection line and overlapping the second edge in the plan view, a 1-3 overlapping connection line adjacent to the 1-1 overlapping connection line and overlapping the fourth edge in the plan view, a 2-1 overlapping connection line disposed on the 1-1 overlapping connection line and overlapping the first edge and the first overlapping portion in the plan view, a 2-2 overlapping connection line adjacent to the 2-1 overlapping connection line and overlapping the 1-2 overlapping connection line, the second edge, the 1-3 overlapping connection line, and the fourth edge in the plan view, and a 2-3 overlapping connection line adjacent to the 2-2 overlapping connection line and overlapping the third edge in the plan view.

In an embodiment, the entirety of the first overlapping portion may overlap the pixel electrode in the plan view.

In an embodiment, the entirety of the second overlapping portion may overlap the pixel electrode in the plan view.

In an embodiment, the 2-1 overlapping connection line may overlap an edge of the first overlapping portion in the plan view.

In an embodiment, the 2-3 overlapping connection line may overlap an edge of the second overlapping portion in the plan view.

In an embodiment, the display device may further include a first overlapping lower line disposed between the substrate and the 1-1 overlapping connection line and overlapping the 2-1 overlapping connection line in the plan view, a second overlapping lower line adjacent to the first overlapping lower line and overlapping the second edge and the fourth edge in the plan view, and a third overlapping lower line adjacent to the second overlapping lower line and overlapping the third edge in the plan view.

In an embodiment, the first overlapping lower line may not overlap the first edge in the plan view.

In an embodiment, the first overlapping lower line may not overlap the first overlapping portion in the plan view.

In an embodiment, the third overlapping lower line may overlap an edge of the 2-3 overlapping connection line in the plan view.

An electronic device according to an embodiment includes a display device and a power supply configured to provide power to the display device, and the display device includes a 1-1 overlapping connection line disposed on a substrate and overlapping a crack bypass propagation area in a plan view; a second overlapping connection line disposed on the 1-1 overlapping connection line and overlapping the crack bypass propagation area and the 1-1 overlapping connection line in the plan view; and a pixel electrode disposed on the second overlapping connection line. A part of the pixel electrode overlapping the crack bypass propagation area overlaps the 1-1 overlapping connection line and the second overlapping connection line.

Therefore, a plurality of metal lines included in a display device according to embodiments of the present invention may overlap each other in a crack bypass propagation area. For example, the overlapping lower line, the gate line, the 1-1 overlapping connection line, the second overlapping connection line, and the pixel electrode may overlap each other in the crack bypass propagation area. In an embodiment, the edges of the metal lines may overlap each other in the crack bypass propagation area. In addition, the fracture strength of each of the metal lines may be greater than the fracture strength of the inorganic insulating layer.

Accordingly, the path along which an impact (e.g., ball-drop) applied to the upper portion of the display panel is transmitted may be extended. In other words, when an impact is applied to the upper portion of the display panel, a crack may occur in the upper portion of the display panel. The crack may be transmitted along the organic layer and the inorganic layer, which have relatively low fracture strengths. In this case, by arranging the metal lines, which have relatively high fracture strengths, to overlap each other in a zigzag pattern in a plan view, the path along which the crack is transmitted may be extended. Accordingly, the shock resistance of the display device may be effectively improved.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a block diagram illustrating a display device according to an embodiment of the present invention.

FIG. 2 is a plan view illustrating a display panel included in the display device of FIG. 1.

FIG. 3 is an enlarged view of area A of FIG. 2.

FIG. 4 is a cross-sectional view illustrating the display panel of FIG. 3.

FIGS. 5 to 8 are plan views illustrating the display panel of FIG. 3.

FIG. 9 is a plan view illustrating a display panel included in the display device according to another embodiment of the present invention.

FIG. 10 is an enlarged view of area C of FIG. 9.

FIG. 11 is a cross-sectional view illustrating the display panel of FIG. 10.

FIGS. 12 to 15 are plan views illustrating the display panel of FIG. 10.

FIG. 16 is a block diagram illustrating an electronic device according to an embodiment.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

Illustrative, non-limiting embodiments will be more clearly understood from the following detailed description in conjunction with the accompanying drawings.

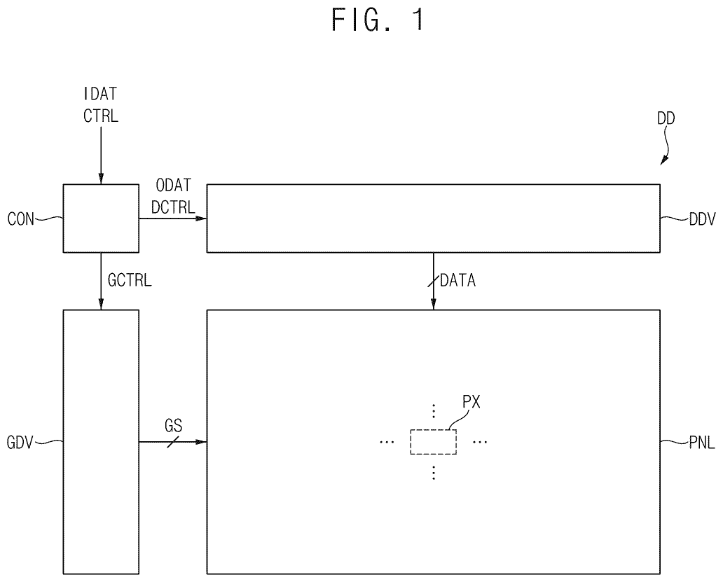

FIG. 1 is a block diagram illustrating a display device according to an embodiment of the present invention.

Referring to FIG. 1, a display device DD according to an embodiment of the present invention may include a display panel PNL, a data driver DDV, a gate driver GDV, and a controller CON.

At least one pixel PX may be arranged on the display panel PNL, and the display panel PNL may be electrically connected to the data driver DDV and the gate driver GDV.

The data driver DDV may generate a data voltage DATA based on output image data ODAT and a data control signal DCTRL. For example, the data driver DDV may generate the data voltage DATA corresponding to the output image data ODAT and may output the data voltage DATA in response to the data control signal DCTRL. The data voltage DATA may be transmitted to the display panel PNL. The data control signal DCTRL may include an output data enable signal, a horizontal start signal, and a load signal. For example, the data driver DDV may be implemented with one or more integrated circuits (IC).

The gate driver GDV may generate a gate signal GS based on a gate control signal GCTRL. The gate signal GS may be transmitted to the display panel PNL. The gate signal GS may include a gate-on voltage for turning on a transistor and a gate-off voltage for turning off the transistor. The gate control signal GCTRL may include a vertical start signal, a clock signal, etc. For example, the gate driver GDV may be directly formed on the display device DD or mounted on the display device DD.

The pixel PX may emit light corresponding to the data voltage DATA in response to the gate signal GS.

The controller CON (e.g., timing controller (T-CON)) may receive input image data IDAT and a control signal CTRL from an external host processor (e.g., GPU). For example, the input image data IDAT may be RGB data including red image data, green image data, and blue image data. The control signal CTRL may include a vertical synchronization signal, a horizontal synchronization signal, an input data enable signal, a master clock signal, etc. The controller CON may generate the gate control signal GCTRL, the data control signal DCTRL, and the output image data ODAT based on the input image data IDAT and the control signal CTRL.

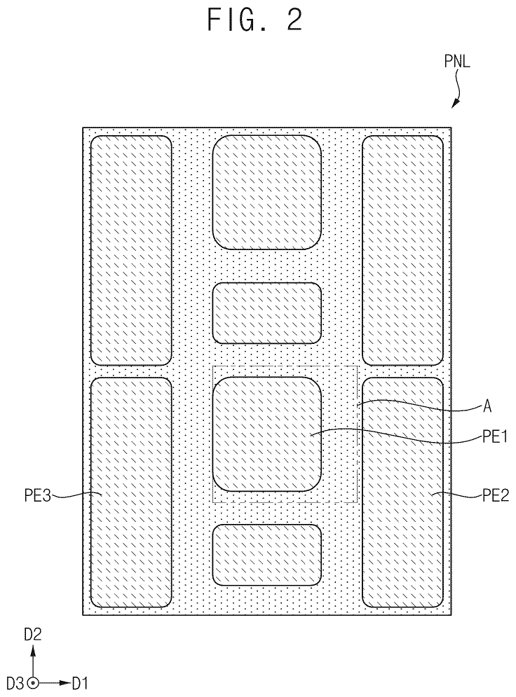

FIG. 2 is a plan view illustrating a display panel included in the display device of FIG. 1. As used herein, the “plan view” is a view in a thickness direction (i.e., third direction DR3) of the display panel PNL.

Referring to FIG. 2, a plurality of pixel electrodes may be arranged on the display panel PNL. In an embodiment, the pixel electrodes may include a first pixel electrode PE1, a second pixel electrode PE2, and a third pixel electrode PE3.

Organic emission layers may be respectively arranged on the first to third pixel electrodes PE1, PE2, and PE3, and each of the organic emission layers may emit light having a predetermined color. For example, an organic emission layer emitting green light may be arranged on the first pixel electrode PE1, an organic emission layer emitting red light may be arranged on the second pixel electrode PE2, and an organic emission layer emitting blue light may be arranged on the third pixel electrode PE3. However, the present invention is not limited thereto.

In an embodiment, the first to third pixel electrodes PE1, PE2, and PE3 may be arranged side by side in a plan view. For example, as shown in FIG. 2, the first to third pixel electrodes PE1, PE2, and PE3 may be arranged in an RGBG structure. However, the present invention is not limited thereto.

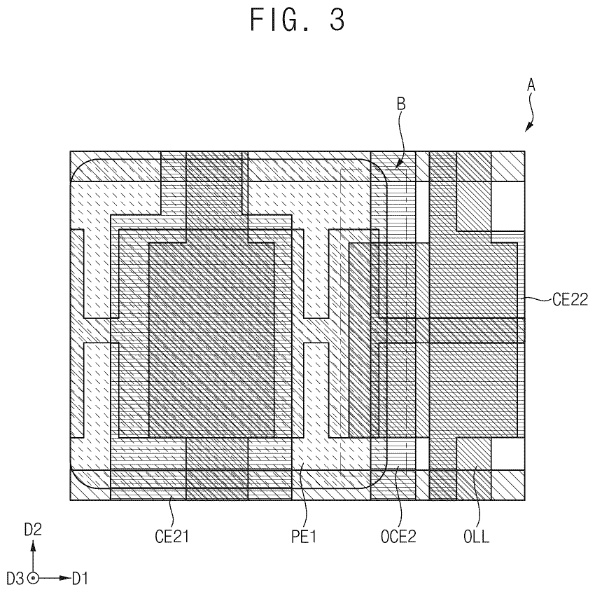

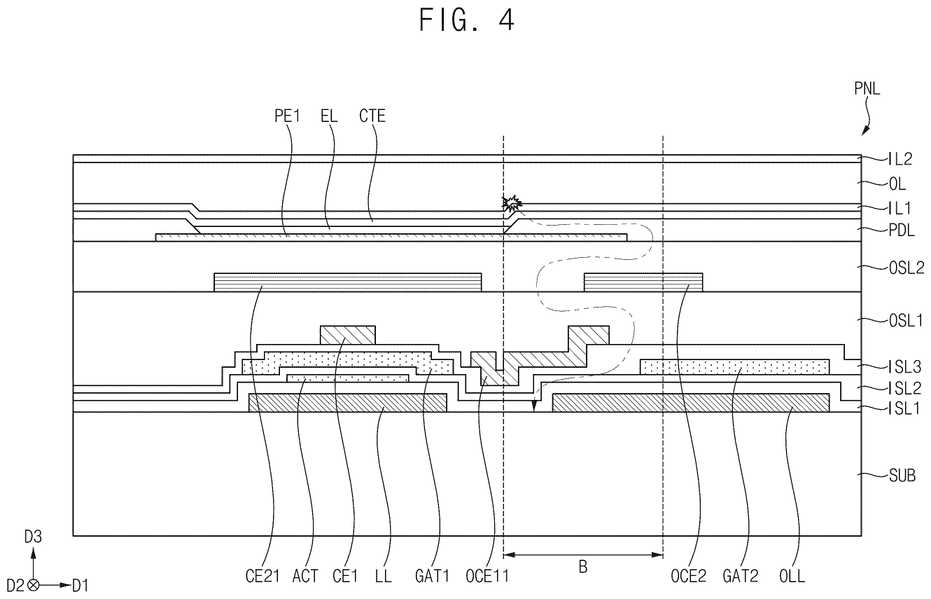

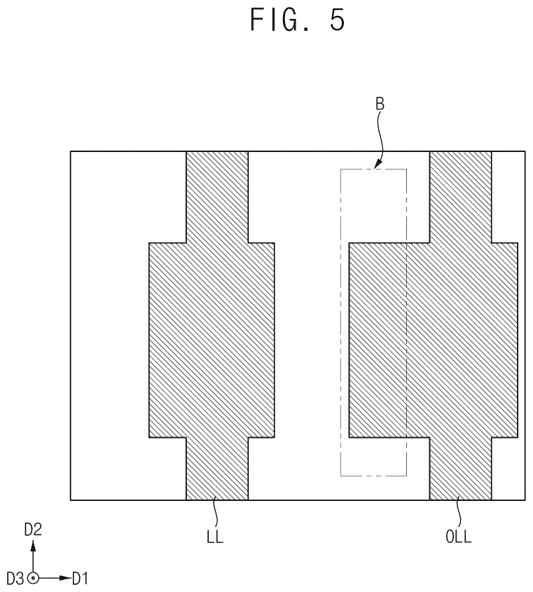

FIG. 3 is an enlarged view of area A of FIG. 2. FIG. 4 is a cross-sectional view illustrating the display panel of FIG. 3. FIGS. 5 to 8 are plan views illustrating the display panel of FIG. 3.

Referring to FIG. 3, a crack bypass propagation area B that partially overlaps the first pixel electrode PE1 may be defined in the display panel PNL. A plurality of metal lines may be stacked and arranged in the crack bypass propagation area B, and the metal lines may overlap each other in a plan view. As the metal lines overlap each other, a path along which a crack generated in the display panel PNL propagates may be extended. This will be described in detail below.

Referring to FIG. 4, the display panel PNL may include a substrate SUB, a lower line LL, an overlapping lower line OLL, a first inorganic insulating layer ISL1, an active pattern ACT, a second inorganic insulating layer ISL2, a first gate line GAT1, a second gate line GAT2, a third inorganic insulating layer ISL3, a first connection line CE1, a 1-1 overlapping connection line OCE11, a 1-2 overlapping connection line OCE12, a 1-3 overlapping connection line OCE13, a first organic insulating layer OSL1, a 2-1 connection line CE21, a 2-2 connection line CE22, a second overlapping connection line OCE2, a second organic insulating layer OSL2, a first pixel electrode PE1, a pixel defining layer PDL, an organic emission layer EL, a common electrode CTE, a first inorganic layer IL1, an organic layer OL, and a second inorganic layer IL2.

In an embodiment, the first pixel electrode PE1 may extend more than the organic emission layer EL in a plan view. The crack bypass propagation area B may start from an end of the organic emission layer EL and extend to cover the part of the first pixel electrode PE1 nonoverlapping the organic emission layer EL in a plan view.

The substrate SUB may include glass, quartz, plastic, or the like. In an embodiment, the substrate SUB may include glass. Accordingly, the display device DD may be a rigid display device. In another embodiment, the substrate SUB may include plastic. Accordingly, the display device DD may be a flexible display device.

Referring to FIGS. 4 and 5, the lower line LL and the overlapping lower line OLL may be disposed on the substrate SUB. In an embodiment, the lower line LL and the overlapping lower line OLL may include a metal, an alloy, a conductive metal oxide, a transparent conductive material, or the like. For example, the lower line LL and the overlapping lower line OLL may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the lower line LL and the overlapping lower line OLL may include molybdenum (Mo).

In an embodiment, as shown in FIGS. 4 and 5, the overlapping lower line OLL may overlap the crack bypass propagation area B. For example, the overlapping lower line OLL may partially overlap the crack bypass propagation area B. In detail, an edge of the overlapping lower line OLL may overlap the crack bypass propagation area B. In other words, the overlapping lower line OLL may have a portion that does not overlap the crack bypass propagation area B, and the crack bypass propagation area B may have an area that does not overlap the overlapping lower line OLL.

Referring again to FIG. 4, the first inorganic insulating layer ISL1 may be disposed on the substrate SUB and may cover the lower line LL and the overlapping lower line OLL. In an embodiment, the first inorganic insulating layer ISL1 may include an inorganic material. For example, the first inorganic insulating layer ISL1 may include silicon oxide, silicon nitride, silicon oxynitride, aluminum oxide, or the like.

The active pattern ACT may be disposed on the first inorganic insulating layer ISL1.

In an embodiment, the active pattern ACT may include a silicon semiconductor. For example, the active pattern ACT may include amorphous silicon, crystalline silicon, or the like.

In another embodiment, the active pattern ACT may include an oxide semiconductor. For example, the active pattern ACT may include zinc (Zn), indium (In), gallium (Ga), tin (Sn), aluminum (Al), zinc oxide (ZnO), indium oxide (InO), indium gallium zinc oxide (In—Ga—Zn—O), zinc tin oxide (Zn—Sn—O), and the like.

The second inorganic insulating layer ISL2 may be disposed on the first inorganic insulating layer ISL1 and may cover the active pattern ACT. In an embodiment, the second inorganic insulating layer ISL2 may include an inorganic material. For example, the second inorganic insulating layer ISL2 may include silicon oxide, silicon nitride, silicon oxynitride, aluminum oxide, or the like.

The first gate line GAT1 and the second gate line GAT2 may be disposed on the second inorganic insulating layer ISL2. In an embodiment, the first gate line GAT1 and the second gate line GAT2 may include a metal, an alloy, a conductive metal oxide, a transparent conductive material, or the like. For example, the first gate line GAT1 and the second gate line GAT2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the first gate line GAT1 and the second gate line GAT2 may include molybdenum (Mo).

In an embodiment, the first gate line GAT1 may overlap the active pattern ACT in a plan view.

In an embodiment, the second gate line GAT2 may overlap the crack bypass propagation area B. For example, the second gate line GAT2 may partially overlap the crack bypass propagation area B. In detail, an edge of the second gate line GAT2 may overlap the crack bypass propagation area B. In other words, the second gate line GAT2 may have a portion that does not overlap the crack bypass propagation area B, and the crack bypass propagation area B may have an area that does not overlap the second gate line GAT2.

The third inorganic insulating layer ISL3 may be disposed on the second inorganic insulating layer ISL2 and may cover the first and second gate lines GAT1 and GAT2. In an embodiment, the third inorganic insulating layer ISL3 may include an inorganic material. For example, the third inorganic insulating layer ISL3 may include silicon oxide, silicon nitride, silicon oxynitride, aluminum oxide, or the like.

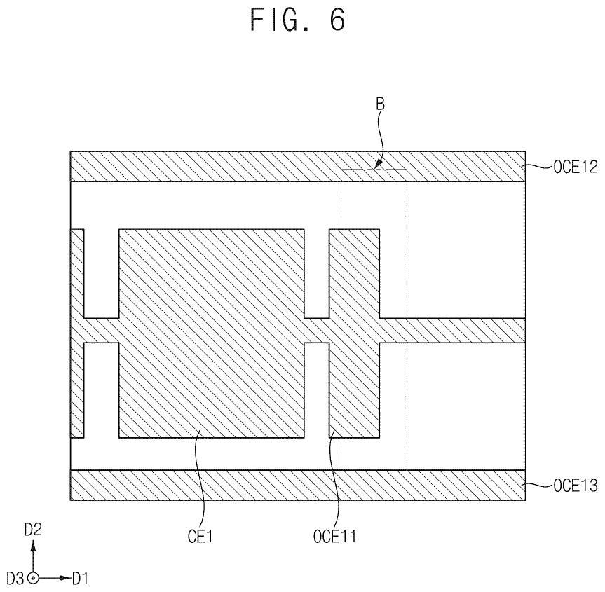

Referring to FIGS. 4 and 6, the first connection line CE1, the 1-1 overlapping connection line OCE11, the 1-2 overlapping connection line OCE12, and the 1-3 overlapping connection line OCE13 may be disposed on the third inorganic insulating layer ISL3. In an embodiment, the first connection line CE1, the 1-1 overlapping connection line OCE11, the 1-2 overlapping connection line OCE12, and the 1-3 overlapping connection line OCE13 may include a metal, an alloy, a conductive metal oxide, a transparent conductive material, or the like. For example, the first connection line CE1, the 1-1 overlapping connection line OCE11, the 1-2 overlapping connection line OCE12, and the 1-3 overlapping connection line OCE13 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the first connection line CE1, the 1-1 overlapping connection line OCE11, the 1-2 overlapping connection line OCE12, and the 1-3 overlapping connection line OCE13 may have a Ti/Al/Ti structure.

In an embodiment, as shown in FIGS. 4 and 6, the 1-1 overlapping connection line OCE11 may overlap the crack bypass propagation area B. For example, the 1-1 overlapping connection line OCE11 may partially overlap the crack bypass propagation area B. In detail, an edge of the 1-1 overlapping connection line OCE11 may overlap the crack bypass propagation area B. In other words, the 1-1 overlapping connection line OCE11 may have a portion that does not overlap the crack bypass propagation area B, and the crack bypass propagation area B may have an area that does not overlap the 1-1 overlapping connection line OCE11.

Referring again to FIG. 4, the first organic insulating layer OSL1 may be disposed on the first connection line CE1, the 1-1 overlapping connection line OCE11, the 1-2 overlapping connection line OCE12, and the 1-3 overlapping connection line OCE13. In an embodiment, the first organic insulating layer OSL1 may include an organic material. For example, the first organic insulating layer OSL1 may include a photoresist, a polyacrylic resin, a polyimide resin, an acrylic resin, or the like.

The 2-1 connection line CE21, the 2-2 connection line CE22, and the second overlapping connection line OCE2 may be disposed on the first organic insulating layer OSL1. In an embodiment, the 2-1 connection line CE21, the 2-2 connection line CE22, and the second overlapping connection line OCE2 may include a metal, an alloy, a conductive metal oxide, a transparent conductive material, or the like. For example, the 2-1 connection line CE21, the 2-2 connection line CE22, and the second overlapping connection line OCE2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the 2-1 connection line CE21, the 2-2 connection line CE22, and the second overlapping connection line OCE2 may have a Ti/Al/Ti structure.

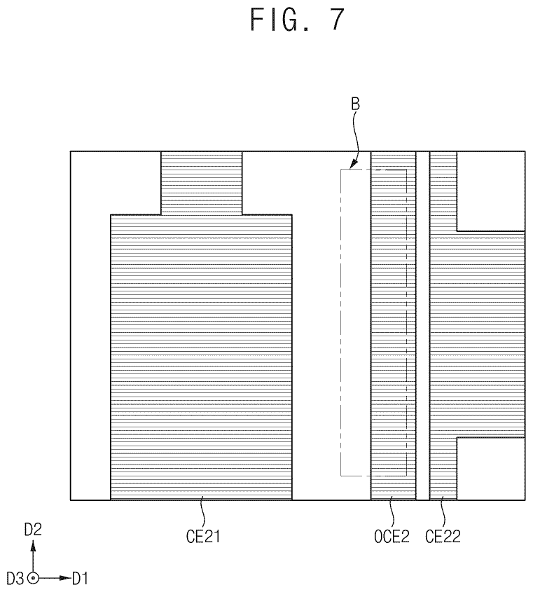

In an embodiment, as shown in FIGS. 4 and 7, the second overlapping connection line OCE2 may overlap the crack bypass propagation area B. For example, the second overlapping connection line OCE2 may partially overlap the crack bypass propagation area B. In detail, an edge of the second overlapping connection line OCE2 may overlap the crack bypass propagation area B. In other words, the second overlapping connection line OCE2 may have a portion that does not overlap the crack bypass propagation area B, and the crack bypass propagation area B may have an area that does not overlap the second overlapping connection line OCE2.

Referring again to FIG. 4, the second organic insulating layer OSL2 may be disposed on the first organic insulating layer OSL1 and may cover the 2-1 connection line CE21, the 2-2 connection line CE22, and the second overlapping connection line OCE2. In an embodiment, the second organic insulating layer OSL2 may include an organic material. For example, the second organic insulating layer OSL2 may include a photoresist, a polyacrylic resin, a polyimide resin, an acrylic resin, or the like.

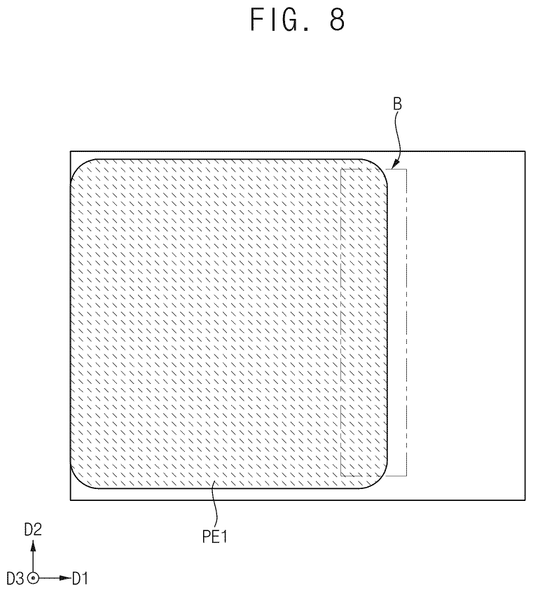

Referring to FIGS. 4 and 8, the first pixel electrode PE1 may be disposed on the second organic insulating layer OSL2. In an embodiment, the first pixel electrode PE1 may include a metal, an alloy, a conductive metal oxide, a transparent conductive material, or the like. For example, the first pixel electrode PE1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the first pixel electrode PE1 may have an ITO/Ag/ITO structure.

In an embodiment, as shown in FIGS. 4 and 8, the first pixel electrode PE1 may overlap the crack bypass propagation area B. For example, the first pixel electrode PE1 may partially overlap the crack bypass propagation area B. In detail, an edge of the first pixel electrode PE1 may overlap the crack bypass propagation area B. In other words, the first pixel electrode PE1 may have a portion that does not overlap the crack bypass propagation area B, and the crack bypass propagation area B may have an area that does not overlap the first pixel electrode PE1.

Referring again to FIG. 4, the pixel defining layer PDL may be disposed on the second organic insulating layer OSL2 and may cover an edge of the first pixel electrode PE1. In an embodiment, the pixel defining layer PDL may include an organic material. For example, the pixel defining layer PDL may include a photoresist, a polyacrylic resin, a polyimide resin, an acrylic resin, or the like.

The organic emission layer EL may be disposed on the first pixel electrode PE1, and the common electrode CTE may be disposed on the organic emission layer EL. The organic emission layer EL may be disposed between the first pixel electrode PEL and the common electrode CTE, and may emit light in response to a voltage difference between the first pixel electrode PE1 and the common electrode CTE.

The first inorganic layer IL1 may be disposed on the common electrode CTE. In an embodiment, the first inorganic layer IL1 may include an inorganic material.

The organic layer OL may be disposed on the first inorganic layer IL1. In an embodiment, the organic layer OL may include an organic material.

The second inorganic layer IL2 may be disposed on the organic layer OL. In an embodiment, the second inorganic layer IL2 may include an inorganic material.

In an embodiment, an edge of the overlapping lower line OLL may overlap an edge of the second gate line GAT2 in the crack bypass propagation area B in a plan view. An edge of the second gate line GAT2 may overlap an edge of the 1-1 overlapping connection line OCE11 in the crack bypass propagation area B in a plan view. An edge of the 1-1 overlapping connection line OCE11 may overlap an edge of the second overlapping connection line OCE2 in the crack bypass propagation area B in a plan view. An edge of the second overlapping connection line OCE2 may overlap the first pixel electrode PE1 in the crack bypass propagation area B in a plan view.

In an embodiment, the fracture strength of the 1-1 overlapping connection line OCE11 may be greater than the fracture strength of the first inorganic insulating layer ISL1 and/or the fracture strength of the second inorganic insulating layer ISL2. The fracture strength of the second overlapping connection line OCE2 may be greater than the fracture strength of the first inorganic insulating layer ISL1 and/or the fracture strength of the second inorganic insulating layer ISL2. As used herein, the “fracture strength” means the maximum stress a material can withstand before breaking.

A plurality of metal lines included in a display device DD according to embodiments of the present invention may overlap each other in a crack bypass propagation area B in a plan view. For example, the overlapping lower line OLL, the second gate line GAT2, the 1-1 overlapping connection line OCE11, the second overlapping connection line OCE2, and the first pixel electrode PE1 may overlap each other in the crack bypass propagation area B in a plan view. In addition, the fracture strength of each of the metal lines may be greater than the fracture strength of an inorganic insulating layer (e.g., the first inorganic insulating layer ISL1 and/or the second inorganic insulating layer ISL2).

Accordingly, a path along which an impact (e.g., a ball-drop) applied to the upper portion of the display panel PNL is propagated may be extended. In other words, as shown in FIG. 4, when an impact is applied to the upper portion of the display panel PNL, a crack may occur in the upper portion of the display panel PNL. The crack propagates along the organic and inorganic layers having relatively low fracture strengths. In this case, by arranging the metal lines having relatively high fracture strengths to overlap in a zigzag pattern, the path along which the crack propagates may be extended. Accordingly, the impact resistance of the display device DD may be effectively improved.

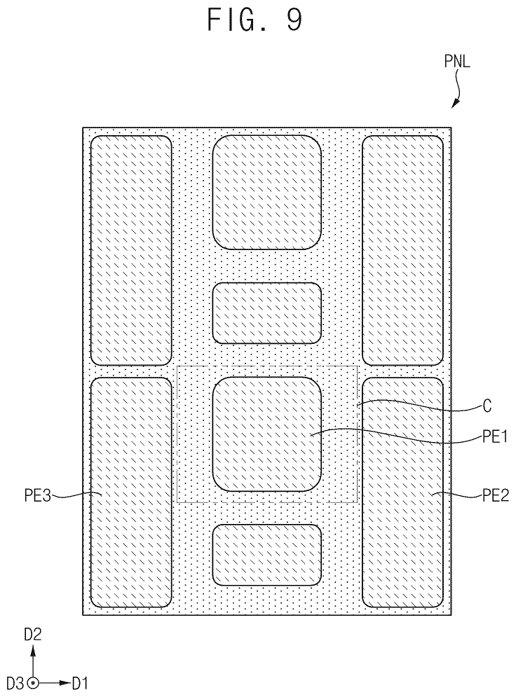

FIG. 9 is a plan view illustrating a display panel included in the display device according to another embodiment of the present invention.

Referring to FIG. 9, a plurality of pixel electrodes may be arranged in a display panel PNL included in a display device according to another embodiment of the present invention. In an embodiment, the pixel electrodes may include a first pixel electrode PE1, a second pixel electrode PE2, and a third pixel electrode PE3.

Organic emission layers may be respectively disposed on the first to third pixel electrodes PE1, PE2, and PE3, and each of the organic emission layers may emit light having a predetermined color. For example, an organic emission layer emitting green light may be disposed on the first pixel electrode PE1, an organic emission layer emitting red light may be disposed on the second pixel electrode PE2, and an organic emission layer emitting blue light may be disposed on the third pixel electrode PE3. However, the present invention is not limited thereto.

In an embodiment, the first to third pixel electrodes PE1, PE2, and PE3 may be arranged side by side in a plan view. For example, as shown in FIG. 9, the first to third pixel electrodes PE1, PE2, and PE3 may be arranged in an RGBG structure. However, the present invention is not limited thereto.

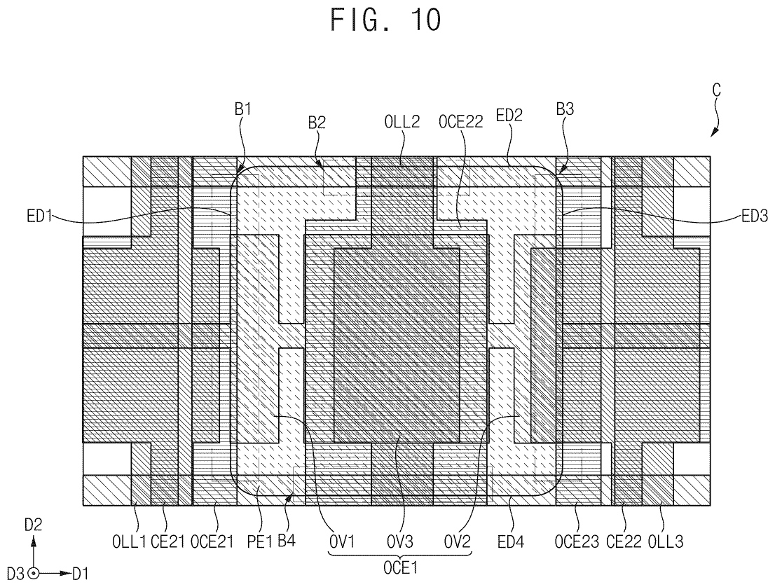

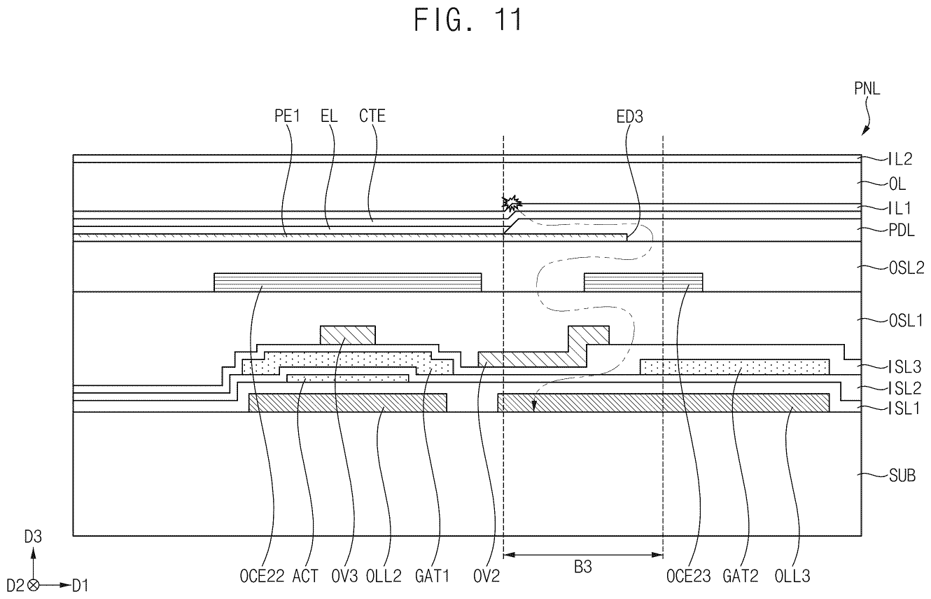

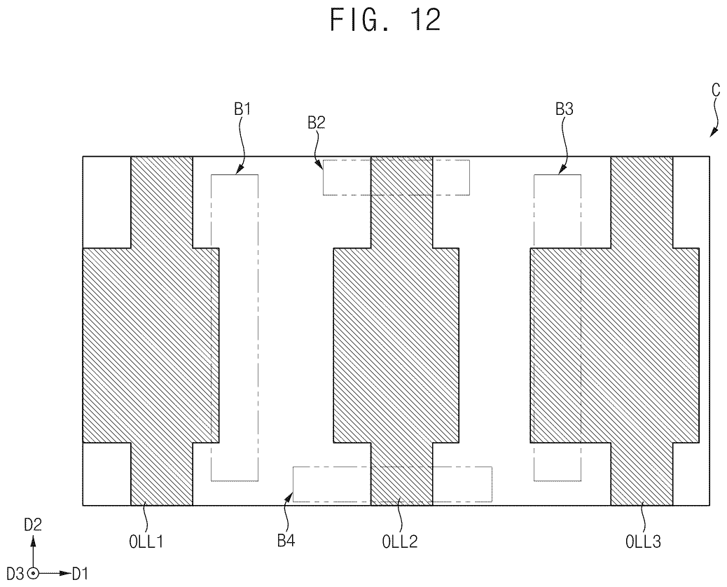

FIG. 10 is an enlarged view of area C of FIG. 9. FIG. 11 is a cross-sectional view illustrating the display panel of FIG. 10. FIGS. 12 to 15 are plan views illustrating the display panel of FIG. 10.

Referring to FIG. 10, at least one crack bypass propagation area that partially overlaps the first pixel electrode PE1 may be defined in the display panel PNL. For example, a first crack bypass propagation area B1, a second crack bypass propagation area B2, a third crack bypass propagation area B3, and a fourth crack bypass propagation area B4 may be defined in the display panel PNL. A plurality of metal lines may be stacked and arranged in each of the first to fourth crack bypass propagation areas B1, B2, B3, and B4, and the metal lines may overlap each other in a plan view. As the metal lines overlap each other, a path along which a crack generated in the display panel PNL propagates may be extended.

In an embodiment, the first pixel electrode PE1 may have a rectangular shape with rounded corners and four sides. For example, the first pixel electrode PE1 may include a first edge ED1, a second edge ED2, a third edge ED3, and a fourth edge ED4. The first edge ED1 may extend in the second direction D2, the second edge ED2 may be connected to the first edge ED1 and may extend in the first direction D1, the third edge ED3 may be connected to the second edge ED2 and may extend in the second direction D2, and the fourth edge ED4 may be connected to the third edge ED3 and may extend in the first direction D1.

In an embodiment, the first to fourth crack bypass propagation areas B1, B2, B3, and B4 may correspond to the first to fourth edges ED1, ED2, ED3, and ED4, respectively. For example, the first to fourth edges ED1, ED2, ED3, and ED4 may overlap the first to fourth crack bypass propagation areas B1, B2, B3, and B4, respectively. This will be described in detail below.

Referring to FIGS. 11 and 12, a first overlapping lower lines OLL1, a second overlapping lower line OLL2, and a third overlapping lower line OLL3 may be disposed on the substrate SUB. In an embodiment, the first to third overlapping lower lines OLL1, OLL2, and OLL3 may include a metal, an alloy, a conductive metal oxide, a transparent conductive material, or the like. For example, the first to third overlapping lower lines OLL1, OLL2, and OLL3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the first to third overlapping lower lines OLL1, OLL2, and OLL3 may include molybdenum (Mo).

In an embodiment, as shown in FIG. 12, the first overlapping lower line OLL1 may overlap the first crack bypass propagation area B1. For example, the first overlapping lower line OLL1 may partially overlap the first crack bypass propagation area B1. In detail, an edge of the first overlapping lower line OLL1 may overlap the first crack bypass propagation area B1. In other words, the first overlapping lower line OLL1 may have a portion that does not overlap the first crack bypass propagation area B1, and the first crack bypass propagation area B1 may have an area that does not overlap the first overlapping lower line OLL1.

In an embodiment, the second overlapping lower line OLL2 may overlap the second crack bypass propagation area B2 and the fourth crack bypass propagation area B4. For example, the second overlapping lower line OLL2 may extend in the second direction D2, a portion of the second overlapping lower line OLL2 may overlap the second crack bypass propagation area B2, and another portion of the second overlapping lower line OLL2 may overlap the fourth crack bypass propagation area B4.

In an embodiment, the third overlapping lower line OLL3 may overlap the third crack bypass propagation area B3. For example, the third overlapping lower line OLL3 may partially overlap the third crack bypass propagation area B3. In detail, an edge of the third overlapping lower line OLL3 may overlap the third crack bypass propagation area B3. In other words, the third overlapping lower line OLL3 may have a portion that does not overlap the third crack bypass propagation area B3, and the third crack bypass propagation area B3 may have an area that does not overlap the third overlapping lower line OLL3.

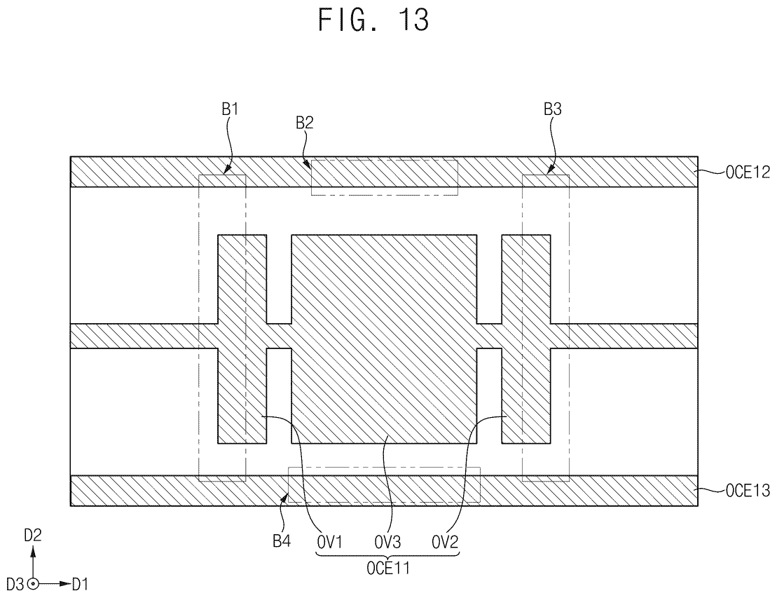

Referring to FIGS. 11 and 13, the first inorganic insulating layer ISL1, the active pattern ACT, the second inorganic insulating layer ISL2, the first gate line GAT1, the second gate line GAT2, and the third inorganic insulating layer ISL3 may be sequentially stacked.

The 1-1 overlapping connection line OCE11, the 1-2 overlapping connection line OCE12, and the 1-3 overlapping connection line OCE13 may be disposed on the third inorganic insulating layer ISL3. In an embodiment, the 1-1 overlapping connection line OCE11, the 1-2 overlapping connection line OCE12, and the 1-3 overlapping connection line OCE13 may include a metal, an alloy, a conductive metal oxide, a transparent conductive material, or the like. For example, the 1-1 overlapping connection line OCE11, the 1-2 overlapping connection line OCE12, and the 1-3 overlapping connection line OCE13 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the 1-1 overlapping connection line OCE11, the 1-2 overlapping connection line OCE12, and the 1-3 overlapping connection line OCE13 may have a Ti/Al/Ti structure.

In an embodiment, the 1-1 overlapping connection line OCE11 may include a first overlapping portion OV1, a second overlapping portion OV2, and a third overlapping portion OV3. For example, the 1-1 overlapping connection line OCE11 may extend in the first direction D1, and the first to third overlapping portions OV1, OV2, and OV3 may protrude in the second direction D2.

In an embodiment, the first overlapping portion OV1 may overlap the first crack bypass propagation area B1. For example, the first overlapping portion OV1 may partially overlap the first crack bypass propagation area B1. In detail, an edge of the first overlapping portion OV1 may overlap the first crack bypass propagation area B1. In other words, the first overlapping portion OV1 may have a portion that does not overlap the first crack bypass propagation area B1, and the first crack bypass propagation area B1 may have an area that does not overlap the first overlapping portion OV1.

In an embodiment, the second overlapping portion OV2 may not overlap the first to fourth crack bypass propagation areas B1, B2, B3, and B4. For example, the entirety of the second overlapping portion OV2 may overlap the first pixel electrode PE1 in a plan view.

In an embodiment, the third overlapping portion OV3 may overlap the third crack bypass propagation area B3. For example, the third overlapping portion OV3 may partially overlap the third crack bypass propagation area B3. In detail, an edge of the third overlapping portion OV3 may overlap the third crack bypass propagation area B3. In other words, the third overlapping portion OV3 may have a portion that does not overlap the third crack bypass propagation area B3, and the third crack bypass propagation area B3 may have an area that does not overlap the third overlapping portion OV3.

In embodiment, the 1-2 overlapping connection line OCE12 may extend in the first direction D1 and may overlap the second crack bypass propagation area B2. For example, the 1-2 overlapping connection line OCE12 may partially overlap the second crack bypass propagation area B2. In detail, an edge of the first-second overlapping connection line OCE12 may overlap the second crack bypass propagation area B2. In other words, the 1-2 overlapping connection line OCE12 may have a portion that does not overlap the second crack bypass propagation area B2, and the second crack bypass propagation area B2 may have an area that does not overlap the 1-2 overlapping connection line OCE12.

In an embodiment, the 1-3 overlapping connection line OCE13 may extend in the first direction D1 and may overlap the fourth crack bypass propagation area B4. For example, the 1-3 overlapping connection line OCE13 may partially overlap the fourth crack bypass propagation area B4. In detail, an edge of the 1-3 overlapping connection line OCE13 may overlap the fourth crack bypass propagation area B4. In other words, the 1-3 overlapping connection line OCE13 may have a portion that does not overlap the fourth crack bypass propagation area B4, and the fourth crack bypass propagation area B4 may have an area that does not overlap the 1-3 overlapping connection line OCE13.

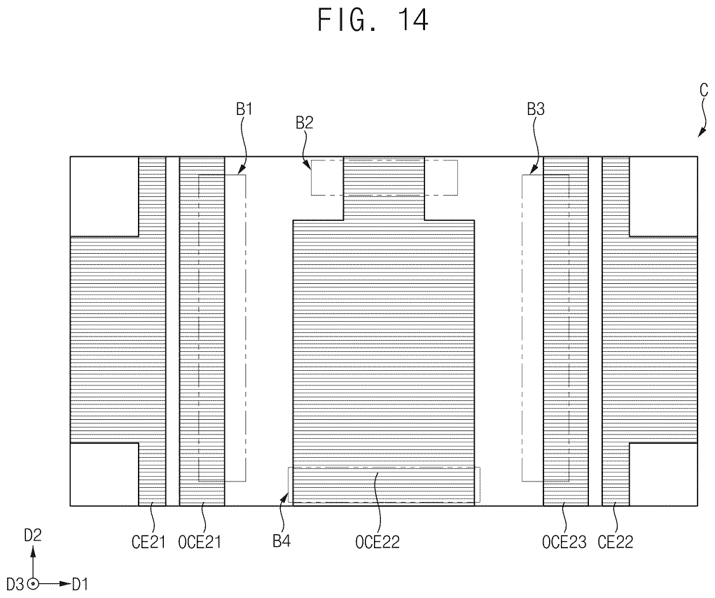

Referring to FIGS. 11 and 14, the first organic insulating layer OSL1 may be disposed on the 1-1 overlapping connection line OCE11.

A 2-1 connection line CE21, a 2-2 connection line CE22, a 2-1 overlapping connection line OCE21, a 2-2 overlapping connection line OCE22, and a 2-3 overlapping connection line OCE23 may be disposed on the first organic insulating layer OSL1. In an embodiment, the 2-1 connection line CE21, the 2-2 connection line CE22, the 2-1 overlapping connection line OCE21, the 2-2 overlapping connection line OCE22, and the 2-3 overlapping connection line OCE23 may include a metal, an alloy, a conductive metal oxide, a transparent conductive material, or the like. For example, the 2-1 connecting line CE21, the 2-2 connecting line CE22, the 2-1 overlapping connecting line OCE21, the 2-2 overlapping connecting line OCE22, and the 2-3 overlapping connecting line OCE23 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. Preferably, the 2-1 connecting line CE21, the 2-2 connecting line CE22, the 2-1 overlapping connecting line OCE21, the 2-2 overlapping connecting line OCE22, and the 2-3 overlapping connecting line OCE23 may have a Ti/Al/Ti structure.

In an embodiment, each of the 2-1 connection line CE21, the 2-2 connection

line CE22, the 2-1 overlapping connection line OCE21, the 2-2 overlapping connection line OCE22, and the 2-3 overlapping connection line OCE23 may extend in the second direction D2. In addition, the 2-1 connection line CE21, the 2-1 overlapping connection line OCE21, the 2-2 overlapping connection line OCE22, the 2-3 overlapping connection line OCE23, and the 2-2 connection line CE22 may be arranged in parallel in the first direction D1.

In an embodiment, the 2-1 overlapping connection line OCE21 may overlap the first crack bypass propagation area B1. For example, the 2-1 overlapping connection line OCE21 may partially overlap the first crack bypass propagation area B1. In detail, an edge of the 2-1 overlapping connection line OCE21 may overlap the first crack bypass propagation area B1. In other words, the 2-1 overlapping connection line OCE21 may have a portion that does not overlap the first crack bypass propagation area B1, and the first crack bypass propagation area B1 may have an area that does not overlap the 2-1 overlapping connection line OCE21.

In an embodiment, the 2-2 overlapping connection line OCE22 may overlap with the second crack bypass propagation area B2 and the fourth crack bypass propagation area B4. For example, the 2-2 overlapping connection line OCE22 may extend in the second direction D2, a portion of the 2-2 overlapping connection line OCE22 may overlap with the second crack bypass propagation area B2, and another portion of the 2-2 overlapping connection line OCE22 may overlap the fourth crack bypass propagation area B4.

In an embodiment, the 2-3 overlapping connection line OCE23 may overlap the third crack bypass propagation area B3. For example, the 2-3 overlapping connection line OCE23 may partially overlap the third crack bypass propagation area B3. In detail, an edge of the 2-3 overlapping connection line OCE23 may overlap the third crack bypass propagation area B3. In other words, the 2-3 overlapping connection line OCE23 may have a portion that does not overlap the third crack bypass propagation area B3, and the third crack bypass propagation area B3 may have an area that does not overlap the 2-3 overlapping connection line OCE23.

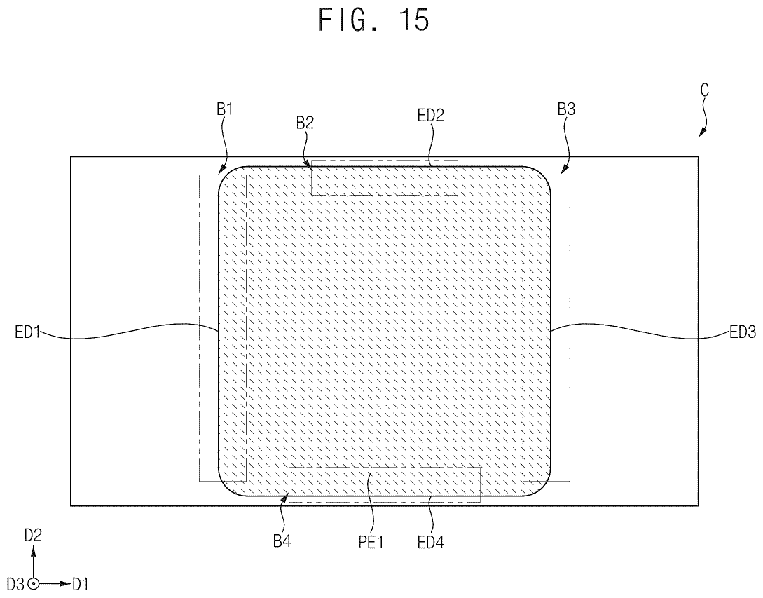

Referring to FIGS. 11 and 15, the first pixel electrode PE1 may be disposed on the second organic insulating layer OSL2. As described above, the first pixel electrode PE1 may include the first to fourth edges ED1, ED2, ED3, and ED4. The first to fourth edges ED1, ED2, ED3, and ED4 may overlap the first to fourth crack bypass propagation areas B1, B2, B3, and B4, respectively.

Referring again to FIG. 10, the first edge ED1 may not overlap the first overlapping lower line OLL1 and may overlap the 2-1 overlapping connection line OCE21 in a plan view. The 2-1 overlapping connection line OCE21 may overlap an edge of the first overlapping portion OV1 and may overlap an edge of the first overlapping lower line OLL1 in a plan view. The entirety of the first overlapping portion OV1 may overlap the first pixel electrode PE1 in a plan view. The first overlapping lower line OLL1 may not overlap the first overlapping portion OV1.

The second edge ED2 may overlap the second overlapping lower line OLL2, may not overlap the third overlapping portion OV3, and may overlap the 2-2 overlapping connection line OCE22 in a plan view. The 2-2 overlapping connection line OCE22 may overlap the third overlapping portion OV3 and may overlap the second overlapping lower line OLL2. The second overlapping lower line OLL2 may overlap the third overlapping portion OV3 in a plan view.

The third edge ED3 may overlap the third overlapping lower line OLL3 and may overlap the 2-3 overlapping connection line OCE23 in a plan view. The 2-3 overlapping connection line OCE23 may overlap an edge of the second overlapping portion OV2 and may overlap the third overlapping lower line OLL3 in a plan view. The entirety of second overlapping portion OV2 may overlap the first pixel electrode PE1 in a plan view. An edge of the third overlapping lower line OLL3 may overlap an edge of the second overlapping portion OV2.

The fourth edge ED4 may overlap the second overlapping lower line OLL2, may not overlap the third overlapping portion OV3, and may overlap the 2-2 overlapping connecting line OCE22 in a plan view.

A plurality of metal lines included in a display device according to embodiments of the present invention may overlap each other in at least one crack bypass propagation area. For example, the crack bypass propagation area may include first to fourth crack bypass propagation areas B1, B2, B3, and B4, and the first to fourth crack bypass propagation areas B1, B2, B3, and B4 may correspond to first to fourth edges ED1, ED2, ED3, and ED4 of a pixel electrode, respectively.

As the crack bypass propagation areas described above are formed in each of the first to fourth edges ED1, ED2, ED3, and ED4, the paths along which the impact applied to the upper portion of the display panel PNL propagates may be further extended.

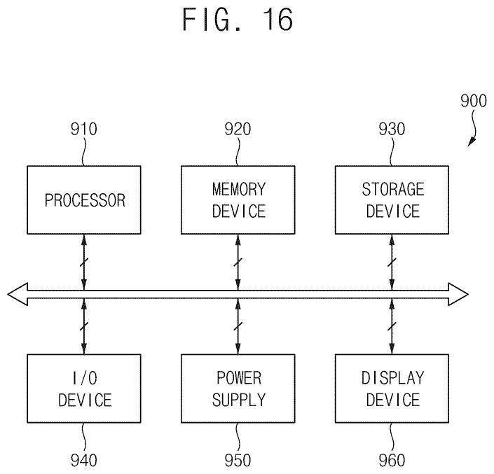

FIG. 16 is a block diagram illustrating an electronic device according to an embodiment.

Referring to FIG. 16, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a 1-1 overlapping connection line disposed on a substrate and overlapping a crack bypass propagation area in a plan view;
a second overlapping connection line disposed on the 1-1 overlapping connection line and overlapping the crack bypass propagation area and the 1-1 overlapping connection line in the plan view; and
a pixel electrode disposed on the second overlapping connection line, wherein a part of the pixel electrode overlapping the crack bypass propagation area overlaps the 1-1 overlapping connection line and the second overlapping connection line in the plan view.

2. The display device of claim 1, wherein the part of the pixel electrode overlaps an edge of the 1-1 overlapping connection line in the plan view.

3. The display device of claim 2, wherein the part of the pixel electrode overlaps an edge of the second overlapping connection line in the plan view.

4. The display device of claim 3, wherein the edge of the 1-1 overlapping connection line overlaps the second overlapping connection line in the plan view.

5. The display device of claim 1, wherein each of the 1-1 overlapping connection line, the second overlapping connection line, and the pixel electrode partially overlaps the crack bypass propagation area in the plan view.

6. The display device of claim 1, further comprising:
at least one inorganic insulating layer disposed between the substrate and the 1-1 overlapping connection line, and
wherein a fracture strength of the pixel electrode is greater than a fracture strength of the at least one inorganic insulating layer.

7. The display device of claim 6, wherein a fracture strength of the 1-1 overlapping connection line is greater than the fracture strength of the at least one inorganic insulating layer, and
wherein a fracture strength of the second overlapping connection line is greater than the fracture strength of the at least one inorganic insulating layer.

8. The display device of claim 1, further comprising:
an overlapping lower line disposed between the substrate and the 1-1 overlapping connection line and overlapping the crack bypass propagation area, the 1-1 overlapping connection line, the second overlapping connection line, and the pixel electrode in the plan view.

9. The display device of claim 8, wherein an edge of the 1-1 overlapping connection line overlaps the overlapping lower line in the plan view.

10. The display device of claim 9, wherein an edge of the second overlapping connection line overlaps the overlapping lower line in the plan view.

11. A display device comprising:
a pixel electrode disposed on a substrate and including a first edge, a second edge connected to the first edge, a third edge connected to the second edge, and a fourth edge connected to the third edge;
in a 1-1 overlapping connection line disposed between the substrate and the pixel electrode and including a first overlapping portion and a second overlapping portion, wherein the first and second overlapping portions overlap the pixel electrode in a plan view;
a 1-2 overlapping connection line adjacent to the 1-1 overlapping connection line and overlapping the second edge in the plan view;
a 1-3 overlapping connection line adjacent to the 1-1 overlapping connection line and overlapping the fourth edge in the plan view;
a 2-1 overlapping connection line disposed on the 1-1 overlapping connection line and overlapping the first edge and the first overlapping portion in the plan view;
a 2-2 overlapping connection line adjacent to the 2-1 overlapping connection line and overlapping the 1-2 overlapping connection line, the second edge, the 1-3 overlapping connection line, and the fourth edge in the plan view; and
a 2-3 overlapping connection line adjacent to the 2-2 overlapping connection line and overlapping the third edge in the plan view.

12. The display device of claim 11, wherein an entirety of the first overlapping portion overlaps the pixel electrode in the plan view.

13. The display device of claim 12, wherein an entirety of the second overlapping portion overlaps the pixel electrode in the plan view.

14. The display device of claim 11, wherein the 2-1 overlapping connection line overlaps an edge of the first overlapping portion in the plan view.

15. The display device of claim 14, wherein the 2-3 overlapping connection line overlaps an edge of the second overlapping portion in the plan view.

16. The display device of claim 11, further comprising:
a first overlapping lower line disposed between the substrate and the 1-1 overlapping connection line and overlapping the 2-1 overlapping connection line in the plan view;
a second overlapping lower line adjacent to the first overlapping lower line and overlapping the second edge and the fourth edge in the plan view; and
a third overlapping lower line adjacent to the second overlapping lower line and overlapping the third edge in the plan view.

17. The display device of claim 16, wherein the first overlapping lower line does not overlap the first edge in the plan view.

18. The display device of claim 16, wherein the first overlapping lower line does not overlap the first overlapping portion in the plan view.

19. The display device of claim 16, wherein the third overlapping lower line overlaps an edge of the 2-3 overlapping connection line in the plan view. 20 An electronic device comprising:
a display device; and
a power supply configured to provide power to the display device,
wherein the display device comprises:
a 1-1 overlapping connection line disposed on a substrate and overlapping a crack bypass propagation area in a plan view;
a second overlapping connection line disposed on the 1-1 overlapping connection line and overlapping the crack bypass propagation area and the 1-1 overlapping connection line in the plan view; and
a pixel electrode disposed on the second overlapping connection line, wherein a part of the pixel electrode overlapping the crack bypass propagation area overlaps the 1-1 overlapping connection line and the second overlapping connection line in the plan view.
